(19) United States
(12) Patent Application Publication
(10) Pub. No.: US 2026/0155661 A1
(43) Pub. Date: Jun. 4, 2026

(54) Energy Storage Apparatus, Method Of Controlling Plurality Of Cells, And Method Of Controlling Energy Storage Apparatus

(71) Applicant: GS Yuasa International Ltd., Kyoto-shi, Kyoto (JP)

(72) Inventors: Akira TOKUSAKA, Kyoto-shi, Kyoto (JP); Satoru NARIMOTO, Kyoto-shi, Kyoto (JP); Atsushi FUKUSHIMA, Kyoto-shi, Kyoto (JP)

(21) Appl. No.: 19/123,516

(22) PCT Filed: Oct. 20, 2023
(86) PCT No.: PCT/JP2023/037972

§ 371 Date: Apr. 23, 2025

(30) Foreign Application Priority Data
Oct. 27, 2022 (JP) 2022-172183

(51) Int. Cl. H02J 7/52; G01R 31/374; G01R 31/3835; H01M 10/42; H01M 10/44; H02J 7/82

(52) U.S. Cl. CPC H02J 7/52; G01R 31/374; G01R 31/3835; H01M 10/425; H01M 10/441; H02J 7/82; H01M 2010/4271

(57) ABSTRACT

An energy storage apparatus includes: a plurality of cells connected in series; a balancer adjusting a variation in discharge capacity for the plurality of cells; and a control unit. The control unit calculates a discharge capacity of each of the cells, based on a full charge capacity of each of the cells after a predetermined time has elapsed from a time point of cell manufacture and a residual capacity of each of the cells after the predetermined time has elapsed from the time point of cell manufacture, and adjusts, by a balancer, a variation in the discharge capacity of each of the cells after the predetermined time has elapsed from the time point of cell manufacture.

### CROSS REFERENCE TO RELATED APPLICATIONS

This application is a National Stage Application, filed under 35 U.S.C. § 371, of International Application No. PCT/JP2023/037972, filed Oct. 20, 2023, which international application claims priority to and the benefit of Japanese Application No. 2022-172183, filed Oct. 27, 2022; the contents of both of which are hereby incorporated by reference in their entirety.

### BACKGROUND

### Technical Field

One aspect of the present invention relates to an energy storage apparatus in which a plurality of storage batteries (secondary batteries), particularly lithium-ion batteries, are connected in series. One aspect of the present invention relates to an energy storage apparatus having a function of removing variations in discharge capacity (the difference between a full charge capacity and a residual capacity of a storage battery) among the storage batteries and maintaining a balance among the storage batteries.

### Description of Related Art

A storage battery is mounted on a transportation means such as an automobile, a railway, a ship, or an aircraft, and is used as a power source for in-cabin lighting, an air conditioner, a communication means, instruments and control equipment necessary for operation, and also as a power source for power equipment. The storage battery can store electric power from a power generation facility or a power generator, and can supply electric power when necessary, and therefore is also used as an industrial electric power supply-demand buffer.

An energy storage apparatus in which a plurality of storage batteries (hereinafter also referred to as cells) are combined is used for mobile objects or for industrial purposes.

It is known that the capacity (full charge capacity and/or residual capacity) of each cell included in the energy storage apparatus varies due to individual internal resistance or other factors.

When charging is performed in a state in which the capacity varies, any of the plurality of cells may be overcharged. As a countermeasure against this, a battery management device includes a function/circuit called a balancer. For example, a cell having a high voltage is discharged by a balancer to eliminate the variation among the plurality of cells. Japanese Unexamined Patent Publication No. 2006-353010 discloses a related technology.

### BRIEF SUMMARY

As described above, the conventional balancer discharges cells having high voltages to eliminate variations among a plurality of cells.

It may be difficult to eliminate the variation in capacity by the conventional balancer. For example, in a case of an energy storage apparatus in which a plurality of lithium-ion batteries (hereinafter also referred to as LFP cells) with an iron-phosphate-based (LiFePO4) active material used in a positive electrode and a carbon-based active material used in a negative electrode are combined, a region (plateau region) in which a voltage value is substantially constant even when a state of charge (SOC) of each cell changes extends over a wide range. In the plateau region, a variation in capacity between the plurality of cells cannot be detected from the voltage value of each cell.

By charging an energy storage apparatus, in which a plurality of LFP cells are combined, to a region close to full charge (region of constant voltage charge), it is possible to detect a capacity variation among the plurality of cells. However, such charging requires time and cost. One aspect of the present invention provides a technology that suppresses variations in capacity among a plurality of cells.

An energy storage apparatus includes: a plurality of cells connected in series; a balancer adjusting a variation in discharge capacity for the plurality of cells; and a control unit. The control unit calculates a discharge capacity of each cell, based on a full charge capacity of each cell after a predetermined time has elapsed from a time point of cell manufacture and a residual capacity of each cell after the predetermined time has elapsed from the time point of cell manufacture, and adjusts, by the balancer, a variation in discharge capacity of each cell after the predetermined time has elapsed time from the time point of cell manufacture.

An energy storage apparatus includes: a plurality of cells connected in series; a voltage measurement unit that measures a voltage of each of the cells; a balancer adjusting a variation in state of charge for the plurality of cells; and a control unit. The control unit calculates a full charge capacity of each cell after a predetermined time has elapsed from a time point of cell manufacture, calculates a state of charge of each cell after the predetermined time has elapsed from the time point of cell manufacture, based on a measured value of a cell voltage by the voltage measurement unit, calculates, from the state of charge of each cell, a difference in the state of charge of each cell after the predetermined time has elapsed from the time point of cell manufacture, and adjusts, by the balancer, a variation in the state of charge of the plurality of cells, based on the full charge capacity of each cell and the difference in the state of charge of each cell.

A method of controlling a plurality of cells connected in series includes: calculating a discharge capacity of each cell, based on a full charge capacity of each cell after a predetermined time has elapsed from a time point of cell manufacture and a residual capacity of each cell after the predetermined time has elapsed from the time point of cell manufacture; and adjusting, by the balancer, a variation in discharge capacity of each cell after the predetermined time has elapsed from the time point of cell manufacture.

A method of controlling an energy storage apparatus including a plurality of cells connected in series includes: calculating, for each cell, a full charge capacity after a predetermined elapsed time from a time point of cell manufacture; acquiring, for each cell, a residual capacity after the predetermined elapsed time from the time point of cell manufacture from a cell voltage; calculating, from the full charge capacity and the residual capacity of each cell, a discharge capacity of each cell after the predetermined elapsed time from the time point of cell manufacture; and equalizing a variation in discharge capacity between the cells.

According to the present technology, by eliminating variations in discharge capacity or state of charge between cells, which occur with a lapse of time from a time point of cell manufacture, it is possible to suppress a cell from overcharging or over-discharging, enabling the cell to fully exhibit performance thereof.

### BRIEF DESCRIPTION OF THE FIGURES

FIG. 1 is a side view of a vehicle.

FIG. 2 is an exploded perspective view of an energy storage apparatus.

FIG. 3 is a sectional view of a cell.

FIG. 4 is a plan view of the cell.

FIG. 5 is a block diagram illustrating an electrical configuration of the energy storage apparatus.

FIG. 6 is a circuit diagram of a balancer.

FIG. 7 is a graph illustrating correlation of SOC-OCV of the cell.

FIG. 8 is a diagram illustrating a manufacturing process of the energy storage apparatus.

FIG. 9 is a flowchart of discharge capacity equalization processing.

FIG. 10 is a diagram illustrating a relationship among a full charge capacity at a time of cell manufacture, and an initial full charge capacity value and an initial residual capacity value of a cell at a time of completion of assembly of the energy storage apparatus.

FIG. 11 is a diagram illustrating a change in discharge capacity.

FIG. 12 is a diagram illustrating a change in capacity after charging.

FIG. 13 is a diagram illustrating a CPU by functional blocks (a diagram illustrating input/output of data processing).

### DETAILED DESCRIPTION OF VARIOUS EMBODIMENTS

(1) An energy storage apparatus according to an embodiment of the present invention includes: a plurality of cells connected in series; a balancer adjusting a variation in discharge capacity for the plurality of cells; and a control unit. The control unit calculates a discharge capacity of each cell, based on a full charge capacity of each cell after a predetermined time has elapsed from a time point of cell manufacture and a residual capacity of each cell after the predetermined time has elapsed from the time point of cell manufacture, and adjusts, by the balancer, a variation in discharge capacity of each cell after the predetermined time has elapsed time from the time point of cell manufacture.

The energy storage apparatus according to an embodiment of the present invention can eliminate a variation in discharge capacity between cells, which occurs with the lapse of time from the time point of cell manufacture. By eliminating the variation in discharge capacity between the cells, it is possible to suppress the cell from overcharging or over-discharging. Additionally, by minimizing excessive safety control that prevent overcharging or over-discharging, the performance of the cell can be fully exhibited.

(2) An energy storage apparatus includes: a plurality of cells connected in series; a voltage measurement unit that measures a voltage of each of the cells; a balancer adjusting a variation in a state of charge for the plurality of cells; and a control unit. The control unit calculates a full charge capacity of each cell after a predetermined time has elapsed from a time point of cell manufacture, calculates a state of charge of each cell after the predetermined time has elapsed from the time point of cell manufacture, based on a measured value of a cell voltage by the voltage measurement unit, calculates, from the state of charge of each cell, a difference in the state of charge of each cell after the predetermined time has elapsed from the time point of cell manufacture, and adjusts, by the balancer, a variation in the state of charge of the plurality of cells, based on the full charge capacity of each cell and the difference in the state of charge of each cell.

According to the energy storage apparatus described in the above (2), it is possible to eliminate the variation in the state of charge between the cells, which occurs with a lapse of time from the time point of cell manufacture. By eliminating the variation in the state of charge between the cells, it is possible to suppress the cell from overcharging or over-discharging. Additionally, by minimizing excessive safety control that prevent overcharging or over-discharging, the performance of the cell can be fully exhibited.

(3) In the energy storage apparatus described in the above (1) or (2), the control unit may calculate a full charge capacity of each cell after a predetermined time has elapsed from a time point of cell manufacture, based on the full charge capacity of the cell at the time point of cell manufacture and a decrease amount of the full charge capacity with a lapse of time from the time point of cell manufacture.

According to the energy storage apparatus described in the above (3), it is possible to accurately obtain the full charge capacity and the discharge capacity of each cell after a predetermined time has elapsed from the time point of cell manufacture. Therefore, estimation accuracy of the difference in discharge capacity between the cells after the predetermined time has elapsed from the time point of cell manufacture is high, and the variation in discharge capacity of the cells can be equalized with high accuracy.

(4) In the energy storage apparatus described in the above (3), the decrease amount of the full charge capacity with an elapsed time after cell manufacture may be calculated based on information on the elapsed time after the cell manufacture and temperature history.

According to the energy storage apparatus described in the above (4), it is possible to accurately obtain the full charge capacity and the discharge capacity of each cell after a predetermined time has elapsed from the time point of cell manufacture. Therefore, estimation accuracy of the difference in discharge capacity between the cells after the predetermined time has elapsed from the time point of cell manufacture is high, and the variation in discharge capacity of the cells can be equalized with high accuracy.

(5) A method of controlling a plurality of cells according to an embodiment of the present invention includes: calculating a discharge capacity of each cell, based on a full charge capacity of each cell after a predetermined time has elapsed from a time point of cell manufacture and a residual capacity of each cell after the predetermined time has elapsed from the time point of cell manufacture; and adjusting, by a balancer, a variation in discharge capacity of each cell after the predetermined time has elapsed from the time point of cell manufacture.

According to the method of controlling a plurality of cells described in the above (5), it is possible to eliminate the variation in discharge capacity between the cells, which occurs with the lapse of time from the time point of cell manufacture. By eliminating the variation in discharge capacity between the cells, it is possible to suppress the cell from overcharging or over-discharging. Additionally, by minimizing excessive safety control that prevent overcharging or over-discharging, the performance of the cell can be fully exhibited.

(6) A method of controlling an energy storage apparatus according to an embodiment of the present invention includes: calculating, for each cell, a full charge capacity after a predetermined elapsed time from a time point of cell manufacture; acquiring, for each cell, a residual capacity after the predetermined elapsed time from the time point of cell manufacture from a cell voltage; calculating, from the full charge capacity and the residual capacity of each cell, a discharge capacity of each cell after the predetermined elapsed time from the time point of cell manufacture; and equalizing a variation in the calculated discharge capacity between the cells.

According to the method of controlling an energy storage apparatus described in the above (6), it is possible to eliminate the variation in discharge capacity between the cells, which occurs with a lapse of time from the time point of cell manufacture. By eliminating the variation in discharge capacity between the cells, it is possible to suppress the cell from overcharging or over-discharging. Additionally, by minimizing excessive safety control that prevent overcharging or over-discharging, the performance of the cell can be fully exhibited.

### Embodiment

### 1. Description of Energy Storage Apparatus 50

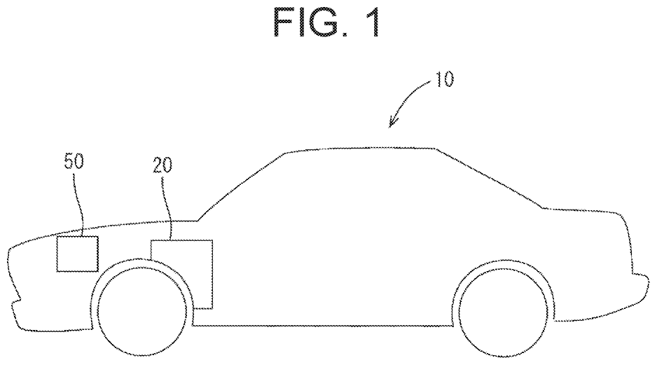

As illustrated in FIG. 1, an engine 20 and an energy storage apparatus 50 used for starting the engine 20, or the like, are mounted on a vehicle 10. In the vehicle 10, in addition to or instead of the engine 20 (an internal combustion engine), a motor may be mounted on the vehicle, and an energy storage apparatus may be mounted as a power source of the motor.

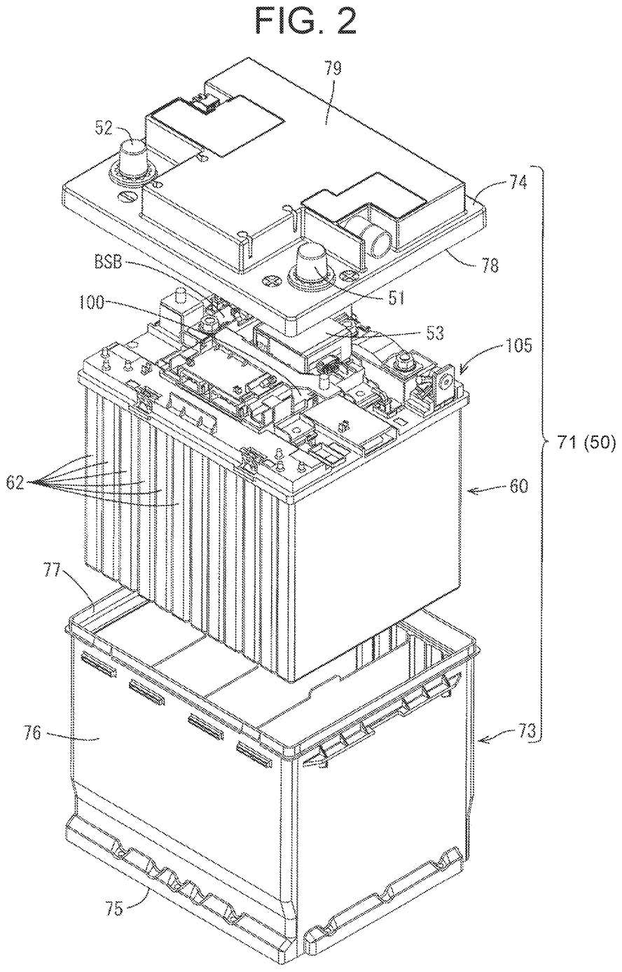

As illustrated in FIG. 2, the energy storage apparatus 50 includes an assembled battery 60, a circuit board unit 105, and an accommodation body 71. The accommodation body 71 includes a main body 73 and a lid body 74, which are made of a synthetic resin material. The main body 73 has a bottom-closed cylindrical shape, and is provided with a bottom surface portion 75 and four side surface portions 76. The four side surface portions 76 form an opening portion 77 in an upper end of the main body 73.

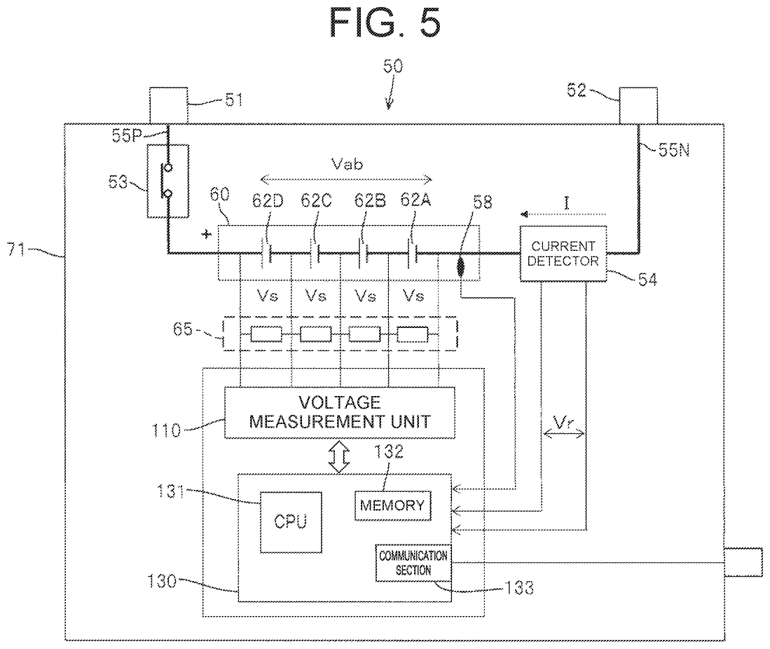

The accommodation body 71 houses therein the assembled battery 60 and the circuit board unit 105. The circuit board unit 105 is a board unit including various types of components (a current interruption device, a current detector, a balancer, a management device, etc., in FIG. 5, which will be described below) on a circuit board 100, and is provided adjacent to, for example, an upper part of the assembled battery 60, as illustrated in FIG. 2. Alternatively, the circuit board unit 105 may be provided adjacent to a side of the assembled battery 60.

The lid body 74 closes the opening portion 77 of the main body 73. An outer peripheral wall 78 is provided around the lid body 74. The lid body 74 has a protruding portion 79 which is substantially T-shaped in plan view. A positive electrode external terminal 51 is fixed to one corner portion of a front portion of the of the lid body 74, and a negative electrode external terminal 52 is fixed to an other corner portion of the front portion of the lid body 74. The circuit board unit 105 may be housed within the lid body 74 (e.g., within the protruding portion 79), instead of within the main body 73 of the accommodation body 71.

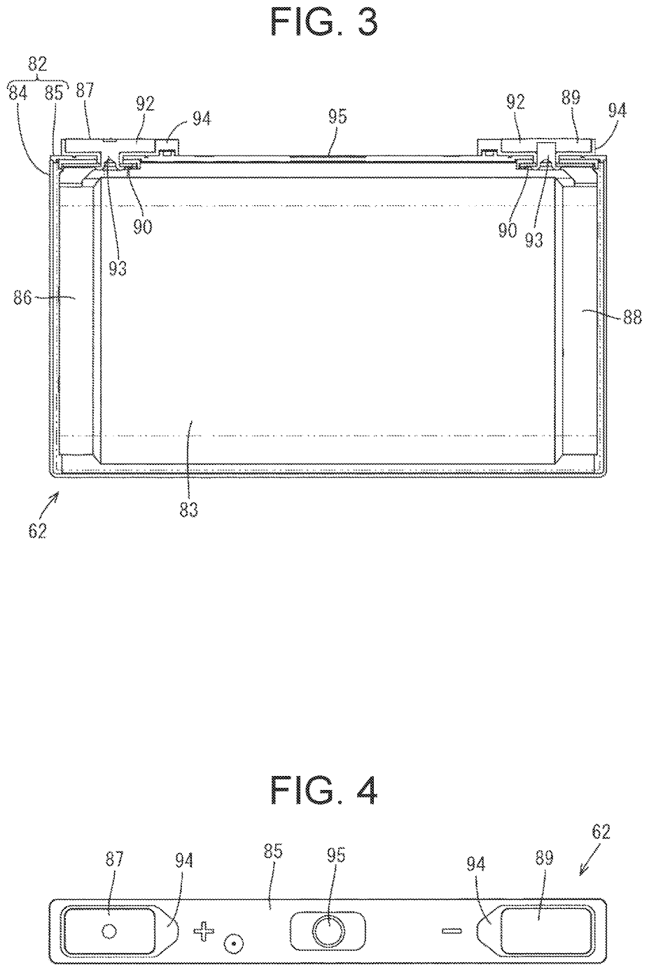

The assembled battery 60 includes a plurality of cells 62. As illustrated in FIG. 3, the cell 62 is configured by accommodating an electrode body 83, together with a non-aqueous electrolyte, in a case 82 having a rectangular parallelepiped shape. The cell 62 is, for example, a lithium-ion secondary battery cell. The case 82 includes a case main-body 84 and a lid 85 that closes an opening portion above the case main-body 84.

Although not illustrated in detail, the electrode body 83 is configured by disposing a separator made of a porous resin film between a negative electrode plate obtained by applying an active material to a base material made of copper foil and a positive electrode plate obtained by applying an active material to a base material made of aluminum foil. These are all in a band shape, and are wound in a flat shape in a state where the negative electrode plate and the positive electrode plate are respectively shifted in positions opposite to each other in a short direction with respect to the separator. The electrode body 83 may be of a laminated type instead of a wound type.

A positive electrode terminal 87 is connected to the positive electrode plate via a positive electrode current collector 86, and a negative electrode terminal 89 is connected to the negative electrode plate via a negative electrode current collector 88. The positive electrode current collector 86 and the negative electrode current collector 88 each include a pedestal portion 90 having a flat plate shape, and a leg portion extending from this pedestal portion 90. A through hole is formed in the pedestal portion 90.

The positive electrode terminal 87 and the negative electrode terminal 89 are each composed of a terminal main-body portion 92 and a shaft portion 93 protruding downward from a central part of a lower surface of the terminal main-body portion 92. The terminal main-body portion 92 and the shaft portion 93 of the positive electrode terminal 87 are integrally formed of aluminum (a single material). In the negative electrode terminal 89, the terminal main-body portion 92 is made of aluminum, the shaft portion 93 is made of copper, and these are assembled together. The terminal main-body portions 92 of the positive electrode terminal 87 and the negative electrode terminal 89 are disposed at both end portions of the lid 85 via gaskets 94 made of an insulating material, and are exposed outward from the gaskets 94, as illustrated in FIG. 4.

The lid 85 includes a pressure release valve (safety valve) 95. The pressure release valve 95 is positioned, for example, between the positive electrode terminal 87 and the negative electrode terminal 89. When an internal pressure of the case 82 exceeds a limit, the pressure release valve 95 is opened to lower the internal pressure of the case 82.

FIG. 5 is a block diagram illustrating an electrical configuration of the energy storage apparatus 50. The energy storage apparatus 50 includes an assembled battery 60, a current detector 54, a current interruption device 53, a balancer 65, a voltage measurement unit 110, a temperature sensor 58, and a management device 130.

There are, for example, twelve cells 62 in the assembled battery 60 (refer to FIG. 2), and the cells 62 are connected such that three cells 62 are connected in parallel and four cells 62 are connected in series. FIG. 5 illustrates three cells 62 connected in parallel by one battery symbol. The cell may be a cylindrical cell or a pouch cell having a laminate film case.

The assembled battery 60, the current interruption device 53, and the current detector 54 are connected in series via a power line 55P and a power line 55N. As the power lines 55P and 55N, bus bars BSB (refer to FIG. 2), which are plate-shaped conductors made of a metallic material such as copper, can be used.

As illustrated in FIG. 5, the power line 55P connects the positive electrode external terminal 51 and the positive electrode of the assembled battery 60. The power line 55N connects the negative electrode external terminal 52 and the negative electrode of the assembled battery 60. The external terminals 51 and 52 are terminals for connection to electric loads provided in the vehicle 10.

The current interruption device 53 is provided in the positive electrode power line 55P. The current interruption device 53 may be a semiconductor switch such as an FET, or may be a relay having a mechanical contact. The current interruption device 53 is preferably a self-holding switch such as a latch relay. The current interruption device 53 is of a normally-closed type, and is controlled to be in a closed state in a normal state. When an abnormality occurs in the energy storage apparatus 50, current I of the assembled battery 60 can be interrupted by switching the current interruption device 53 from a closed state to an open state.

The current detector 54 is provided in the negative electrode power line 55N. The current detector 54 may be a shunt resistor. The resistive current detector 54 can measure the current I of the assembled battery 60, based on a voltage Vr between both ends of the current detector 54. The resistive current detector 54 can distinguish between discharging and charging, based on the polarity (positive or negative) of the voltage Vr. Alternatively, the current detector 54 may be a magnetic sensor.

The voltage measurement unit 110 can measure a voltage Vs of each of cells 62A to 62D and a total voltage Vab of the assembled battery 60. The temperature sensor 58 is attached to the assembled battery 60, and detects a temperature of the assembled battery 60.

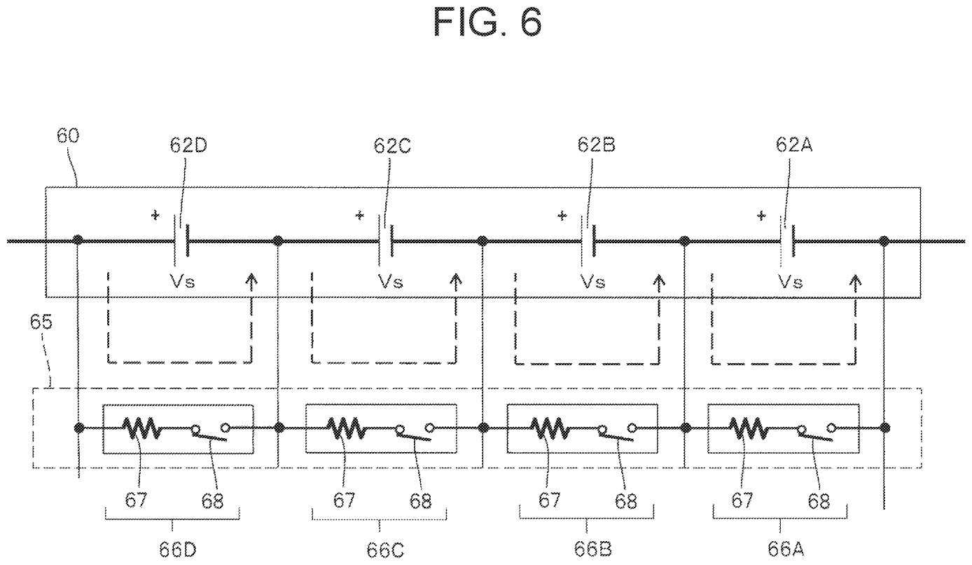

The balancer 65 is used to equalize the voltages Vs of the cells 62, and includes four cell discharge circuits 66A to 66D in the present embodiment, as illustrated in FIG. 6.

Each of the cell discharge circuits 66A to 66D is connected in parallel to each of the cells 62A to 62D. Each of the cell discharge circuits 66A to 66D includes a discharge resistor 67 and a switch 68. By turning on the switch 68, the corresponding cell 62 can be discharged.

The management device 130 is mounted on the circuit board 100 (refer to FIG. 2), and includes a CPU 131, a memory 132, and a communication section 133, as illustrated in FIG. 5. The communication section 133 is connected to a vehicle ECU via a communication port 134.

The management device 130 monitors the state of the energy storage apparatus 50, based on the outputs of the voltage measurement unit 110, the current detector 54, and the temperature sensor 58. That is, the management device 130 monitors the cell voltage Vs of each cell 62, the temperature of the assembled battery 60, the current I, and the total voltage Vab. The management device 130 corresponds to a “control unit”.

The memory 132 stores therein an execution program of an equalization process for adjusting discharge capacities DC of the cells 62A to 62D, and data necessary for executing these programs. The data stored in the memory 132 includes, for example, data of an SOC-OCV characteristic of the cell 62 to be described next, inspection data (to be described below) of a full charge capacity of each cell 62 at the time of cell manufacture, and the like.

The program may be distributed by using a telecommunication line.

### 2. SOC-OCV Characteristic of Cell 62

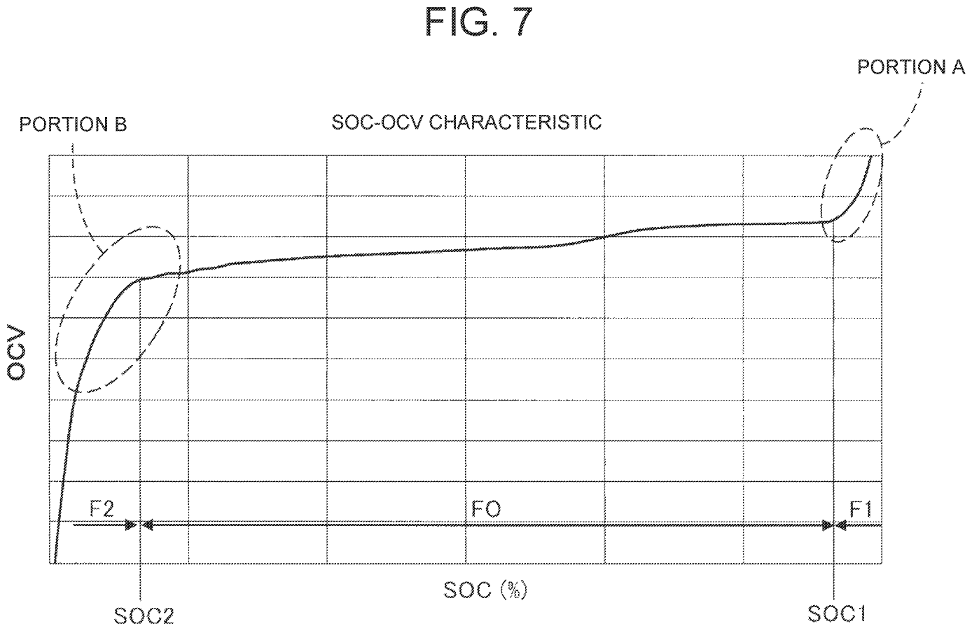

FIG. 7 is a graph illustrating, as an example, SOC-OCV characteristics of the LFP cell 62 with an iron phosphate-based (LiFePO4) active material used in the positive electrode and a carbon-based active material used in the negative electrode, where the horizontal axis represents SOC [%] and the vertical axis represents OCV [V]. The OCV (Open Circuit Voltage) may be a cell voltage when there is no current, which is not affected by polarization, or a cell voltage Vs when it can be considered that there is no current. The case where it can be regarded as no current is a case where the current is equal to or less than a predetermined value (for example, a case where a dark current flows).

The SOC is a ratio of a residual capacity [Ah] to a full charge capacity [Ah]; and is expressed by the following expression (1).

$$SOC = ( Y / X ) \times 100 \qquad ( 1 )$$

Here, X is the full charge capacity of the cell, and Y is the residual capacity of the cell (the amount of electricity stored in the cell).

In the SOC-OCV characteristic, the cell 62 has a plateau region F0, a first rapidly-changing region F1, and a second rapidly-changing region F2. The plateau region F0 is a range in which the SOC is from SOC2 (30%) to SOC1 (95%). The plateau region F0 is a region in which a change in OCV with respect to a change in SOC is equal to or less than a predetermined value, and in which the graph is substantially flat.

The first rapidly-changing region F1 is a region in which the SOC is equal to or greater than SOC1, and the second rapidly-changing region F2 is a region in which the SOC is equal to or less than SOC2. Both the first rapidly-changing region F1 and the second rapidly-changing region F2 have a larger slope of the graph than that of the plateau region F0, and the OCV rapidly changes with respect to the SOC change.

Since the cell 62 has the first rapidly-changing region F1, the cell voltage Vs rapidly increases in the vicinity of full charge in the final stage of charging (portion A in FIG. 7). In addition, since the cell 62 has the second rapidly-changing region F2, the cell voltage Vs rapidly decreases in the final stage of discharge (portion B in FIG. 7).

The cell 62 having such characteristics is not limited to the LFP cell.

### 3. Discharge Capacity Equalization Method in Manufacturing Process

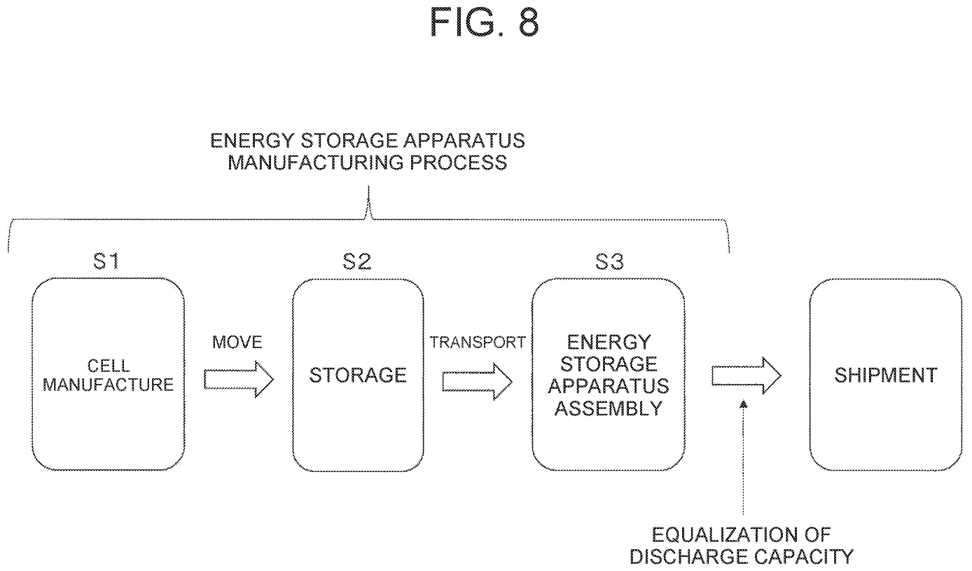

The manufacturing process of the energy storage apparatus 50 includes, for example, a cell manufacturing process S1, a storage process S2, and an energy storage apparatus assembly process S3, as illustrated in FIG. 8. In some cases, the storage process S2 is skipped, and the process immediately proceeds to the energy storage apparatus assembly process S3.

S1 is a process of manufacturing the cell 62, and S2 is a process of moving and storing the manufactured cell 62 in a predetermined warehouse or the like whose temperature is managed. S3 is a process of assembling components (the battery case 20, the lid member 50, the cells 62A to 62D, the circuit board unit 105, and the like) to produce the energy storage apparatus 50.

Factors of variation in discharge capacity among a plurality of cells in an energy storage apparatus are as follows.
(1) Variation in full charge capacity between cells during cell manufacturing (due to individual difference between cells)
(2) Variation in degradation of the full charge capacity between cells due to storage and transport during manufacturing of the energy storage apparatus
(3) Variation in cell self-discharge between cells after cell manufacturing (due to individual difference between cells)

Hereinafter, a method of eliminating the variation in discharge capacity between cells, which occurs in an energy storage apparatus manufacturing process (from cell manufacturing to energy storage apparatus assembly), will be disclosed.

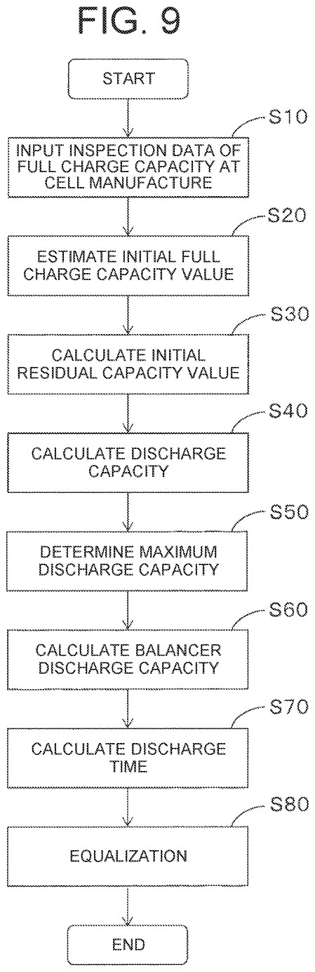

FIG. 9 is a flowchart of a discharge capacity equalization method. The discharge capacity equalization method includes eight steps from S10 to S80 in order to equalize the discharge capacities DC of the cells 62A to 62D connected in series.

As illustrated in FIG. 8, the equalization of the discharge capacities (from S20 to S80) is a process performed after the assembly of the energy storage apparatus 50 and before shipment.

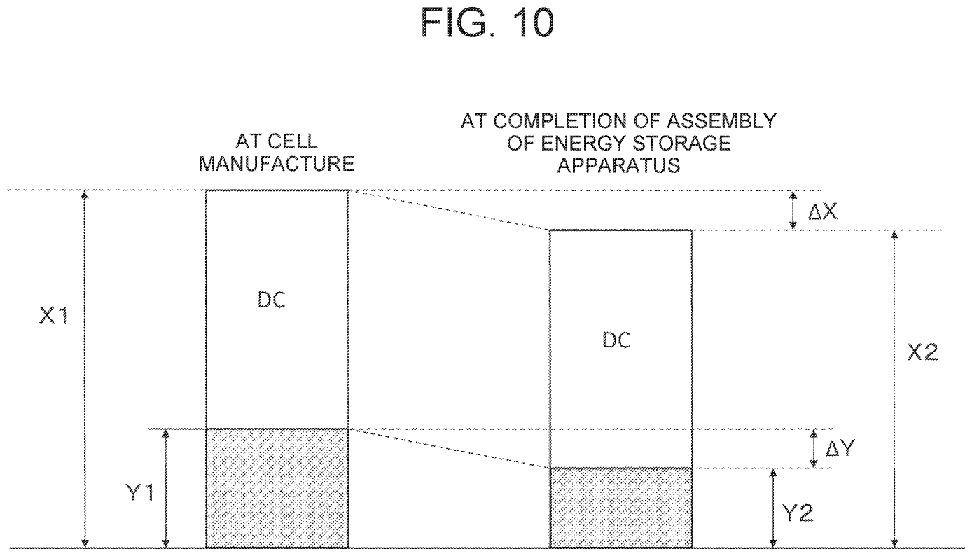

When the cells are manufactured, a full charge capacity X1 [Ah] of each of the cells 62A to 62D is measured (refer to FIG. 10). In S10, after the energy storage apparatus is assembled, a measurement result of the full charge capacity X1 of each cell 62 during cell manufacture is input to the memory 132 of the management device 130 incorporated in the energy storage apparatus 50. This will be described in detail below.

S20 or thereafter is a flow from a time point onwards of completion of assembly of the energy storage apparatus 50. In S20, the management device 130 estimates an initial full charge capacity value X2 [Ah] of each of the cells 62A to 62D at the time point of completion of assembly of the energy storage apparatus 50 (refer to FIG. 10). The initial full charge capacity value X2 is a full charge capacity at a time point of activation of the management device 130 (at the start of data processing), after the energy storage apparatus 50 is assembled. The same applies to an initial residual capacity value Y2 to be described below.

As illustrated in Equation (2), the initial full charge capacity value X2 can be estimated by subtracting, from the full charge capacity X1 at the time of cell manufacture, a decrease amount AX accompanying a lapse of time (which refers to a lapse of a predetermined time or a lapse of an arbitrary time) after cell manufacture.

$$X 2 = X 1 - Δ X \qquad ( 2 )$$

Since the cell naturally degrades even due to neglect (also referred to as “neglect-induced degradation” or “degradation over time”), the full charge capacity decreases by the decrease amount AX. This is an unintended irreversible reaction, and is one of the factors of a decrease in full charge capacity.

This step of calculating the decrease amount AX is an important step for equalizing the variation in discharge capacity.

In the present embodiment, the decrease amount AX of the full charge capacity X1 is determined in consideration of the temperature history of the cell (an ambient temperature during storage or during transport), in addition to the time elapsed from the time point of cell manufacture. By considering the temperature history of the cell in addition to the elapsed time, it is possible to accurately calculate the decrease amount AX of the full charge capacity X1. A neglect-induced degradation amount, i.e., the decrease amount AX depends on time (for example, a root of time or a root of N-th power), and is proportional to a constant that depends on temperature.

A reaction rate of the above-described unintended reaction also depends on the temperature.

Therefore, the temperature is also an important element that affects the decrease amount AX. Note that, strictly speaking, a degradation phenomenon unique to each cell progresses, but if the material (related substances) and configuration thereof are the same, AX is often substantially the same.

It may be considered that there is no variation in degradation described above in (2) for each cell as long as the material (related substance) and the configuration thereof are the same.

Hereinafter, it is assumed that the temperature of each cell changes in the same manner from the time point of cell manufacture to the time point of completion of assembly of the energy storage apparatus 50.

Further, if the temperature history of each cell and the time elapsed from the time point of cell manufacture to the time pint of completion of assembly of the energy storage apparatus 50 are the same (if the cells are stored under the same conditions), the neglect-induced degradation amount, i.e., the decrease amount AX, can be considered to be the same.

In S30, the management device 130 determines an initial residual capacity value Y2 [Ah] of each cell 62 at the time point of completion of assembly of the energy storage apparatus 50 (refer to FIG. 10). Note that the time elapsed from the time point of cell manufacture to the time point of completion of assembly of the energy storage apparatus 50 can be obtained from some kind of time management, such as time management of processes using a server or the like. A code (a barcode or a two-dimensional code) may be printed on the cell in advance, and a time at the time point of cell manufacture may be stored. That is, information of the code is read by a reader or the like at the time of assembling the energy storage apparatus 50, and the time elapsed from the time point of cell manufacture to the time point of completion of assembly of the energy storage apparatus 50 can be calculated from the time point of cell manufacture to the time point of completion of assembly of the energy storage apparatus 50, as stored in the code. Accordingly, the decrease amount AX, which is also the neglect-induced degradation amount, can be obtained.

When a temperature change from the time point of cell manufacture to the time point of completion of assembly of the energy storage apparatus 50 is taken into consideration, the decrease amount AX can be obtained with higher accuracy. As described above, when the temperature change has occurred, a constant in the vicinity of a certain temperature is multiplied by a time-dependent amount (time for which the state is in the vicinity of the temperature) to obtain a sectional amount of neglect-induced degradation at the certain temperature, and the sectional amounts of neglect-induced degradation are added up, whereby a total amount of neglect-induced degradation, i.e., the decrease amount AX can be obtained.

A specific example will be described below, but this is merely an example, and a method other than this may be employed. First, after completion of aging and lid attachment, the capacities of the cells 62A to 62D are measured. The voltage and the current of the cell are measured, and the capacity of the cell is acquired from the relationship between the current integrated value and the SOC-OCV characteristic. Accordingly, the full charge capacity X1 of each of the cells 62A to 62D can be acquired.

After the measurement, each of the cells 62A to 62D is discharged. At this time point, the voltage of each of the cells 62A to 62D is measured, and the initial residual capacity value Y1 can be acquired from the SOC-OCV characteristic relationship. As described above, time information is obtained at this time point. The information may be saved in a manufacturing/process management server, or may be recorded in a barcode, a two-dimensional code, or the like. The following control steps may be performed by the manufacturing/process management server or may be performed by the management device 130. Alternatively, a work tool (a dedicated terminal such as a personal computer or a tablet) to be used by a worker during manufacturing may be used.

Next, the process proceeds to an assembly process of the energy storage apparatus 50. The worker or the manufacturing machine assembles the assembled battery 6062, attaches other components such as the management device 130, and completes the assembly of the energy storage apparatus 50.

Thereafter, as described above, the time at the time point of cell manufacture is acquired from a barcode, a two-dimensional code, or the like attached to the server or the cell, and is compared with the current time to obtain the time elapsed from the time point of cell manufacture to the time point of completion of assembly of the energy storage apparatus 50.

From the elapsed time, it is possible to obtain an amount of degradation by which each of the cells 62A to 62D has degraded from the time point of cell manufacture to the time point of completion of assembly of the energy storage apparatus 50, i.e., the decrease amount AX, which is also a neglect-induced degradation amount. Next, the cell voltage Vs of each of the cells 62A to 62D is measured by using the voltage measurement unit 110. From a measured value of the cell voltage Vs, SOC [%] of each of the cells 62A to 62D is obtained with reference to the SOC-OCV characteristic illustrated in FIG. 7.

In the present embodiment, for example, when the assembly of the energy storage apparatus 50 is completed, the SOC of each of the cells 62A to 62D is obtained by using the characteristic (SOC-OCV) of the second rapidly-changing region F2, which is illustrated in FIG. 7. Therefore, the SOC of each of the cells 62A to 62D can be estimated with high accuracy.

This is because discharge is performed after the cell capacity at the time point of cell manufacture is obtained, and the SOC of each of the cells 62A to 62D is obtained by using the characteristic (SOC-OCV) of the second rapidly-changing region F2. By setting the cell to have a low SOC, assembly can be performed safely, or progress of battery degradation can be suppressed.

Then, the management device 130 calculates, from the obtained SOC, an initial residual capacity value Y2 [Ah] of each of the cells 62A to 62D at the time point of completion of assembly of the energy storage apparatus 50. The initial residual capacity value Y2 can be obtained by multiplying the SOC by the full charge capacity X2. In the present embodiment, the initial residual capacity value Y2 is obtained by using the SOC-OCV characteristic, but may be calculated by using a residual capacity Y-OCV characteristic.

AY illustrated in FIG. 10 is a difference between the initial residual capacity values Y1 and Y2 at the time point of cell manufacture and at the time point of completion of assembly of energy storage apparatus. AY is due to self-discharge between the cells 62A to 62D.

In S40, the management device 130 subtracts the initial residual capacity value Y2 calculated in S30 from the initial full charge capacity value X2 calculated in S20, thereby determining the discharge capacity DC [Ah] of each of the cells 62A to 62D at the time point of assembly of the energy storage apparatus (refer to FIG. 10).

$$DC = X 2 - Y 2 \qquad ( 3 )$$

In S50, the management device 130 compares the discharge capacities DC of the cells 62A to 62D calculated in S40, and determines a cell having a maximum discharge capacity DCmax.

Thereafter, in S60, the management device 130 subtracts the discharge capacity DC from the maximum discharge capacity DCmax, as indicated by Equation (4), to determine a balancer discharge capacity (an amount of electricity to be discharged by the balancer 65) S of each of the cells 62A to 62D.

$$S = DC max - DC \qquad ( 4 )$$

In S70, the management device 130 determines a discharge time T of each of the cells 62A to 62D from the balancer discharge capacity S calculated in S60.

In S80, the management device 130 operates the balancer 65 to discharge each of the cells 62A to 62D for the discharge time T calculated in S70. As described above, the discharge capacities DC of the cells 62A to 62D can be equalized. The processing from S20 to S80 is performed, for example, after the assembly of the energy storage apparatus 50 is completed.

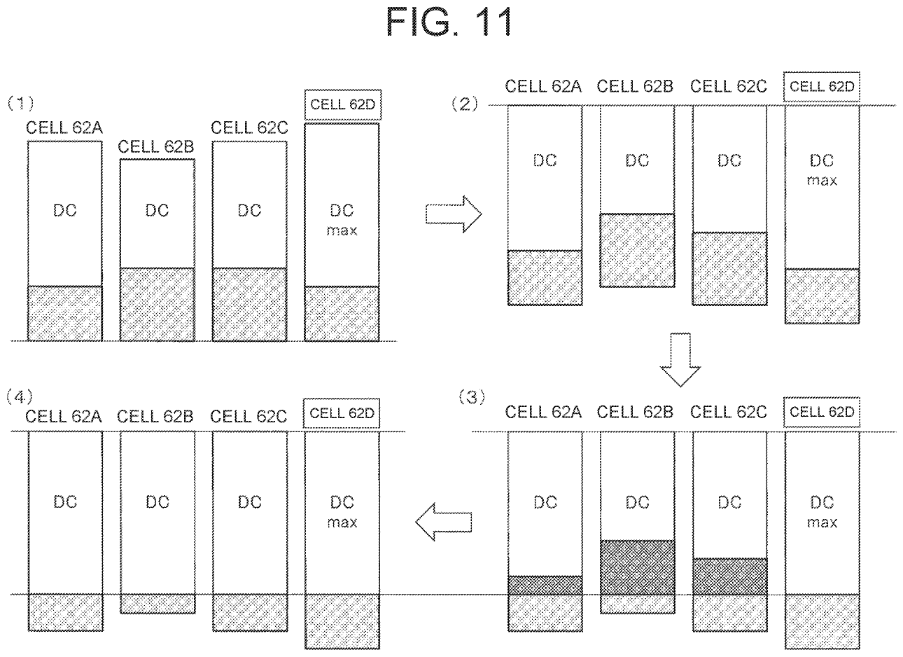

FIG. 11 is a diagram illustrating changes in the discharge capacity DC of each of the cells 62A to 62D; (1) illustrates the discharge capacity DC at the time point of cell manufacture; (2) and (3) illustrate the discharge capacity DC at the time point of comparison; and (4) illustrates the discharge capacities DC after equalization.

In the example of FIG. 11, the cell 62D is a cell having the maximum discharge capacity DCmax, and the discharge capacities DC of each of the cells 62A to 62C can be equalized to the maximum discharge capacity DCmax by discharging, in the cells 62A to 62C, the balancer discharge capacity S calculated in S60.

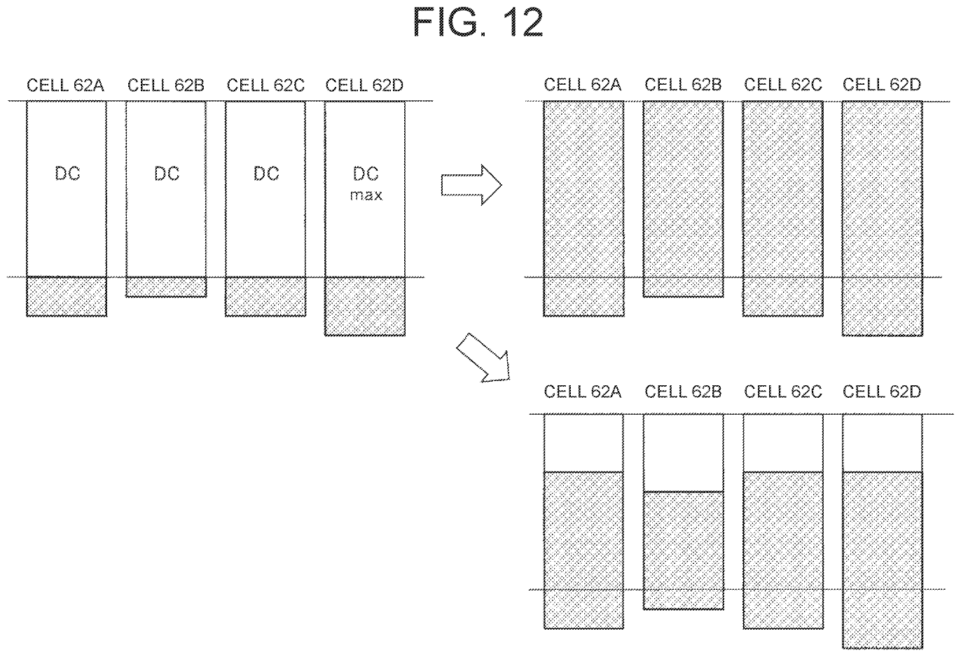

By equalizing the discharge capacities DC of the cells 62A to 62D, as illustrated in FIG. 12, the cells 62A to 62D are uniformly charged after shipment, and therefore, it is possible to suppress the voltages Vs of some of the cells 62A to 62D from rising and becoming overcharged in the final stage of charging. The same applies during discharge, which leads to prevention of over-discharge (in the case of discharge, the SOC, rather than the discharge capacity DC, is equalized).

In addition, when there is an abnormality (for example, an internal short circuit or the like) in some of the cells 62A to 62D, a difference in the cell voltage Vs occurs with the lapse of time after the energy storage apparatus is manufactured, and the cell voltage Vs of the abnormal cell decreases.

Therefore, by leaving the cells 62A to 62D for a predetermined time and comparing the cell voltages Vs, it is also possible to detect abnormality in the cells 62A to 62D before shipment. In addition, it is possible to detect a cell having a smaller full charge capacity than that of a normal cell, such as an abnormally degraded cell.

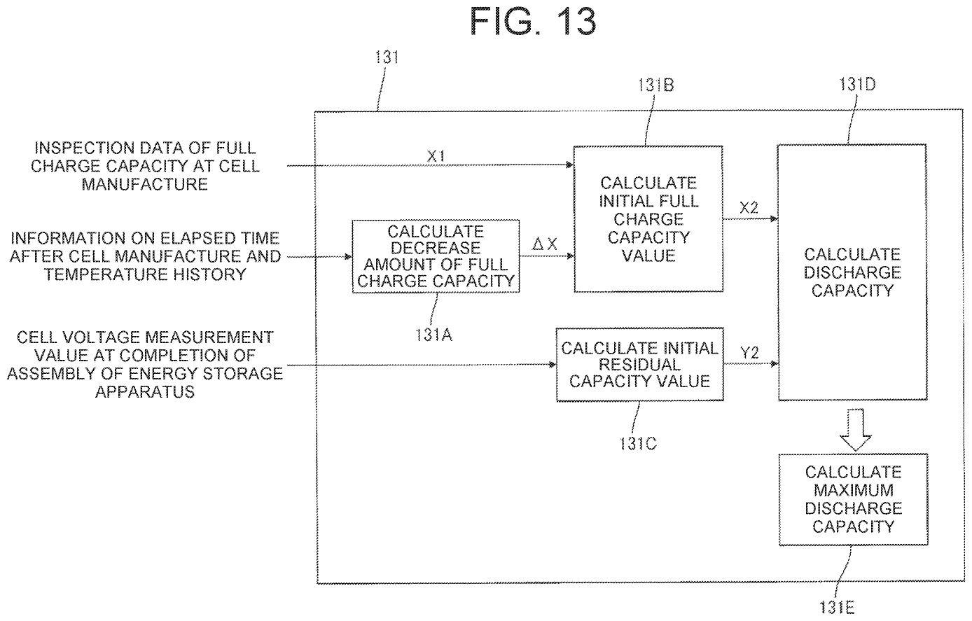

FIG. 13 illustrates data processing related to elimination of variation in the discharge capacity DC by arithmetic blocks. Further, in this example, a case where the management device 130 performs a series of processes will be described. In the arithmetic blocks in FIG. 13, the CPU 131 includes a first arithmetic block 131A, a second arithmetic block 131B, a third arithmetic block 131C, a fourth arithmetic block 131D, and a fifth arithmetic block 131E.

The first arithmetic block 131A calculates a decrease amount AX of a full charge capacity X1 of each of the cells 62A to 62D, based on information on the elapsed time after cell manufacture and temperature history. The second arithmetic block 131B calculates an initial full charge capacity value X2 of each of the cells 62A to 62D at the time point of completion of assembly of the energy storage apparatus, based on inspection data of the full charge capacity X1 at the time of cell manufacture and the decrease amount AX of the full charge capacity X1 calculated by the first arithmetic block 131A.

The third arithmetic block 131C calculates an initial residual capacity value Y2 of each of the cells 62A to 62D, based on the measured value of the cell voltage Vs at the time point of completion of assembly of the energy storage apparatus. The fourth arithmetic block 131D calculates a discharge capacity DC of each of the cells 62A to 62D from the initial full charge capacity value X2 calculated by the second arithmetic block 131B and the initial residual capacity value Y2 calculated by the third arithmetic block 131C.

Then, the fifth arithmetic block 131E compares the discharge capacity DC of each of the cells 62A to 62D calculated by the fourth arithmetic block 131D, determines a maximum discharge capacity DCmax, and calculates a balancer discharge capacity S of each of the cells 62A to 62C.

Functional blocks in FIG. 13 illustrate data processing necessary for calculating the maximum discharge capacity DC and the balancer discharge capacity S of each of the cells 62, and the CPU 131 may execute these processes by a dedicated arithmetic circuit or may execute these processes by a program.

### 4. Effect

According to the present disclosure, by eliminating variations in discharge capacity DC among cells, which occurs from the time point of cell manufacture, it is possible to suppress overcharging or over-discharging, enabling the cell 62 to fully exhibit performance thereof.

Further, since the discharge capacities DC of the cells 62A to 62D can be equalized even if the cells 62A to 62D are not charged to full charge after the energy storage apparatus is manufactured, constant voltage charging (CV charging) using a dedicated charging apparatus is not necessary, and a work time (tact time) does not become long. Therefore, there is an advantage in that the energy storage apparatus 50 can be delivered early.

According to the present disclosure, since the information on the temperature history is taken into consideration in addition to the elapsed time after cell manufacture, it is possible to accurately estimate the decrease amount AX of the full charge capacity X1 after cell manufacture. In particular, the manufacturing process of the energy storage apparatus 50 (from cell manufacturing to energy storage apparatus assembly) is often temperature-controlled, and a highly accurate temperature history can be obtained. Therefore, an estimation error of the decrease amount AX of the full charge capacity X1 is small, and the discharge capacity DC and the variation in discharge capacity of the cell 62 can be estimated with high accuracy.

According to the present disclosure, in S30, since the SOC is estimated by using the low SOC rapidly-changing region F2 (a portion B in FIG. 7), the SOC of each of the cells 62A to 62D can be estimated with high accuracy, without charging the cell 62 to the high SOC rapidly-changing region F1.

According to the present disclosure, since the initial full charge capacity value X2 of the cell 62 can be estimated with high accuracy, improvement in accuracy of life prediction of the cell 62 can also be expected.

### OTHER EMBODIMENTS

The present invention is not limited to the embodiments explained with reference to the above description and the drawings, and the technical scope of the present invention also incorporates therein, for example, the following embodiments.

(1) The cell (repeatedly chargeable and dischargeable energy storage cell) 62 is not limited to a lithium ion secondary battery cell, and may be an other non-aqueous electrolyte secondary battery cell. A capacitor can also be used instead of the secondary battery cell 62. Further, the SOC-OCV characteristic of the cell is not limited to the characteristic having the plateau region as illustrated in FIG. 7, and may be a characteristic having no plateau region.

(2) In the above-described embodiment, the energy storage apparatus 50 is mounted on the vehicle (automobile) 10, however may be mounted on a mobile object other than a vehicle, such as a ship or an aircraft. Further, the present invention may be used for, not limited to the mobile object, a stationary application such as an energy storage apparatus for fluctuation absorption in a distributed power generation system, or an uninterruptible power supply (UPS).

(3) In the above-described embodiment, the balancer 65 is the discharge circuit 66 using a resistor, but the balancer may be any circuit as long as the cell 62 can be individually discharged. The cell 62 may be discharged by using a circuit element other than a resistor.

(4) In the above-described embodiment, equalization of the discharge capacity DC (discharge of the balancer discharge capacity S by the balancer) is performed in a period from completion of assembly of the energy storage apparatus 50 to shipment thereof. If necessary data is stored in the memory 132, the full charge capacity X2 of each cell 62 after a predetermined time has elapsed from the time point of cell manufacture can be obtained. Therefore, it is also possible to calculate the discharge capacity DC of each cell 62, based on the full charge capacity X2 of each cell 62 after the predetermined time has elapsed from the time point of cell manufacture and the residual capacity Y2 of each cell 62 after the predetermined time has elapsed from the time point of cell manufacture, and to equalize the discharge capacities DC among the cells at a time point when a predetermined time has elapsed from the time of cell manufacture (after shipment or after mounting on a vehicle). The necessary data is information such as inspection data of the full charge capacity X1 at the time of cell manufacture, an elapsed time after cell manufacture, and temperature history.

(5) In the above-described embodiment, the decrease amount AX of the full charge capacity X1 of the cell 62 is calculated based on the elapsed time after cell manufacture and the temperature history. For example, when there is almost no temperature change after the cell is manufactured, the decrease amount AX of the full charge capacity X1 of the cell 62 may be calculated based on only the elapsed time after cell manufacture.

(6) In the above-described embodiment, the discharge capacity DC of each cell 62 is made uniform by discharging each cell 62 with reference to the cell 62 having the maximum discharge capacity. The discharge capacity DC of each cell 62 may be made uniform by a method other than that of the embodiment as long as the method is a method of discharging a cell 62 having a shallow discharge capacity DC.

(7) Further, in the above-described embodiment, the technique of eliminating variation in discharge capacity of the cell 62 by using the discharge capacity DC has been described, however, the problem of the present invention can also be solved by using the SOC (state of charge). For example, the cell voltage Vs of each cell 62 after a predetermined time has elapsed from the time point of cell manufacture can be measured by the voltage measurement unit 110, and the SOC of each cell 62 after a predetermined time has elapsed from the time point of cell manufacture can be calculated by referring to the SOC-OCV characteristic from the measured value of the cell voltage Vs. By comparing the calculated SOCs of the cells 62, an SOC difference between the cells can be obtained, and by adjusting the obtained SOC difference by the balancer 65, the SOCs of the cells 62 can be equalized.

Since the SOC is a relative value (a ratio between the full charge capacity X2 and the residual capacity Y2), even if the SOC difference is zero, a difference in the residual capacity Y2 may occur due to a difference in the full charge capacity X2. Therefore, when the SOCs are equalized, in addition to the SOC of each cell 62 at the time point when the predetermined time has elapsed from the time of cell manufacture, the full charge capacity X2 at the time point when the predetermined time has elapsed from the time of cell manufacture may be considered.

In other words, the variation in SOC (state of charge) of the plurality of cells 62 may be adjusted based on the full charge capacity X2 of each of the cells 62 at the time point when a predetermined time has elapsed from the time of cell manufacture, in addition to the SOC difference between the cells 62.

For example, the discharge time of each cell 62 calculated from the SOC difference is corrected by using the full charge capacity X2. The discharge time T of the cell 62 having a large full charge capacity X2 is set to be longer than that of the cell 62 having a small full charge capacity X2. Then, the balancer 65 discharges each cell 62 for the discharge time after the correction. By doing so, it is possible to equalize the residual capacity difference and the SOC difference among the cells with high accuracy while considering the difference in the full charge capacity X2. Needless to say, the full charge capacity may be considered not only by correcting (adjusting) the discharge time, but also by other methods. As described in the first embodiment, the full charge capacity X2 at the time point when a predetermined time has elapsed from the time of cell manufacture can be calculated based on the full charge capacity X1 at the time of cell manufacture and the decrease amount AX of the full charge capacity X1 with a lapse of time from the time point of cell manufacture. As described above, the balancer can be similarly controlled by replacing the discharge capacity DC with a state of charge (SOC). Further, although the SOC is defined as the state of charge, this is a matter of definition, and the state of charge can also be considered to be replaced with a voltage or an amount of electricity.

Therefore, the same control can be performed by replacing the discharge capacity DC with a variable such as a voltage or an amount of electricity.

1. An energy storage apparatus comprising:
a plurality of cells connected in series;
a balancer adjusting a variation in discharge capacity for the plurality of cells; and
a control unit, wherein
the control unit
calculates a discharge capacity of each cell, based on a full charge capacity of each cell after a predetermined time has elapsed from a time point of cell manufacture and a residual capacity of each cell after the predetermined time has elapsed from the time point of cell manufacture, and
adjusts, by the balancer, a variation in discharge capacity of each cell after the predetermined time has elapsed from the time point of cell manufacture.

2. An energy storage apparatus comprising:
a plurality of cells connected in series;
a voltage measurement unit measuring a voltage of each of the cells;
a balancer adjusting a variation in state of charge for the plurality of cells; and
a control unit, wherein
the control unit
calculates a full charge capacity of each cell after a predetermined time has elapsed from a time point of cell manufacture,
calculates a state of charge of each cell after the predetermined time has elapsed from the time point of cell manufacture, based on a measured value of a cell voltage by the voltage measurement unit,
calculates, from the state of charge of each cell, a difference in the state of charge of each cell after the predetermined time has elapsed from the time point of cell manufacture, and
adjusts, by the balancer, a variation in state of charge of the plurality of cells, based on a difference between the full charge capacity of each cell and the state of charge of each cell.

3. The energy storage apparatus according to claim 1, wherein
the control unit calculates a full charge capacity of each cell after the predetermined time has elapsed from the time point of cell manufacture, based on the full charge capacity of the cell at the time point of cell manufacture and a decrease amount of a full charge capacity with a lapse of time from the time point of cell manufacture.

4. The energy storage apparatus according to claim 3, wherein
the control unit calculates a decrease amount of the full charge capacity with an elapsed time after cell manufacture, based on information on the elapsed time after cell manufacture and temperature history.

5. A method of controlling a plurality of cells, the method adjusting, by a balancer, a variation in discharge capacity for the plurality of cells connected in series, the method comprising:
calculating a discharge capacity of each cell, based on a full charge capacity of each cell after a predetermined time has elapsed from a time point of cell manufacture and a residual capacity of each cell after the predetermined time has elapsed from the time point of cell manufacture; and
adjusting, by the balancer, a variation in discharge capacity of each cell after the predetermined time has elapsed from the time point of cell manufacture, thereby equalizing the discharge capacities of the cells.

6. A method of controlling an energy storage apparatus including a plurality of cells connected in series, the method comprising:
calculating, for each cell, a full charge capacity after a predetermined elapsed time from a time of cell manufacture;
acquiring, for each cell, a residual capacity after the predetermined elapsed time from the time of cell manufacture, from a cell voltage; and
calculating, from a full charge capacity and a residual capacity of each cell, a discharge capacity of each cell after the predetermined elapsed time from the time of cell manufacture, and adjusting a variation in discharge capacity of each cell.
